(19) United States
(12) Patent Application Publication
(10) Pub. No.: US 2009/0160545 A1
(43) Pub. Date: Jun. 25, 2009

(54) DUAL VOLTAGE SWITCHING CIRCUIT

(75) Inventor: KE-YOU HU, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/033,873

(22) Filed: Feb. 19, 2008

(30) Foreign Application Priority Data
Dec. 19, 2007 (CN) 200710203222.3

(51) Int. Cl. H03H 11/24

(52) U.S. Cl. 327/581

(57) ABSTRACT

A dual voltage switching circuit includes an input terminal receiving a control signal, an output terminal, three transistors, and a Zener diode. The gate of the first transistor is connected to the input terminal. The drain of the first transistor is connected to a standby power and the gate of the second transistor. The drain of the second transistor is connected to a first system power and the gate of the third transistor. The sources of the first transistor and the second transistor are grounded. The drain of the third transistor is connected to the input terminal. The source of the third transistor is connected to a second system power. The anode of the Zener diode is connected to the standby power. The cathode of the Zener diode is connected to the output terminal. The output terminal selectively outputs the standby power or the second system power.

### BACKGROUND OF THE INVENTION

1. Field of the Invention

The present invention relates to dual voltage switching circuit for a computer, and more particularly to a low cost dual voltage switching circuit which can prevent the computer from being down when the computer is waken up.

2. Description of related art

In general, a user can make a computer enter a sleep mode through a user setting in advanced configuration and power interface (ACPI), in order to protect the computer and save energy. The user can also wake up the sleeping computer by use of peripheral equipment such as a keyboard or mouse.

A working voltage is provided by a dual voltage switching circuit. When the computer is in a work mode, the dual voltage switching circuit provides a 5V system (5V_SYS) voltage. When the computer is in the sleep mode, the dual voltage switching circuit provides a 5V standby (5V_SB) voltage.

Referring to FIG. 2, a typical dual voltage switching circuit for a computer includes four metal-oxide-semiconductor field-effect transistors (MOSFETs) Q10, Q20, Q30, and Q40. The MOSFETs Q10, Q20, and Q30 are N-channel MOSFETs. The MOSFET Q40 is a P-channel MOSFET. The gate of the MOSFET Q10 is connected to a terminal 10. The source of the MOSFET Q10 is grounded. The drain of the MOSFET Q10 receives a 5V_SB voltage. The gate of the MOSFET Q20 is connected to the drain of the MOSFET Q10. The source of the MOSFET Q20 is grounded. The drain of the MOSFET Q20, the gate of the MOSFET Q30, and the gate of the MOSFET Q40 receive a 12V_SYS voltage. The source of the MOSFET Q30 receives a 5V_SYS voltage. The drain of the MOSFET Q30 is connected to a terminal 20. The source of the MOSFET Q40 receives the 5V_SB voltage. The drain of the MOSFET Q40 is connected to the terminal 20.

A working process of the typical dual voltage switching circuit includes two stages. In the first stage, the computer is in a sleep mode, and a low level voltage from the computer is input to the gate of the MOSFET Q10 via the terminal 20. The MOSFET Q10 is turned off and the MOSFET Q20 is turned on. An output voltage at the drain of the MOSFET Q20 is at a low level. The MOSFET Q40 is turned on and the MOSFET Q30 is turned off. Therefore the terminal 10 outputs the 5V_SB voltage in the first stage. In the second stage, the computer is in a work mode, and a power-ok (PWR-OK) signal from the computer is input to the gate of the MOSFET Q10 via the terminal 20. The MOSFET Q10 is turned on and an input voltage at the gate of the MOSFET Q20 is at a low level. Therefore the MOSFET Q20 is turned off and the 12V_SYS voltage is output to the gates of the MOSFET Q30 and the MOSFET Q40. The MOSFET Q30 is turned on and the MOSFET Q40 is turned off. Therefore the terminal 10 outputs the 5V_SYS voltage in the second stage. That is, when the PWR-OK signal is input to the typical dual voltage switching circuit, the terminal 10 outputs the 5V_SYS voltage.

However, the typical dual voltage switching circuit has four MOSFETs which is costly.

What is needed, therefore, is a dual voltage switching circuit which can solve the above problem.

### SUMMARY

An exemplary dual voltage switching circuit includes an input terminal receiving a control signal, an output terminal, three transistors, and a Zener diode. The gate of the first transistor is connected to the input terminal. The drain of the first transistor is connected to a standby power and the gate of the second transistor. The drain of the second transistor is connected to a first system power and the gate of the third transistor. The source of the first transistor and the source of the second transistor are grounded. The drain of the third transistor is connected to the input terminal. The source of the third transistor is connected to a second system power. The anode of the Zener diode is connected to the standby power. The cathode of the Zener diode is connected to the output terminal. The output terminal selectively outputs the standby power or the second system power.

Other advantages and novel features will become more apparent from the following detailed description when taken in conjunction with the accompanying drawings, in which:

### BRIEF DESCRIPTION OF THE DRAWINGS

FIG. 1 is a circuit diagram of one embodiment of a dual voltage switching circuit in accordance with the present invention; and

FIG. 2 is a circuit diagram of a conventional dual voltage switching circuit for a computer.

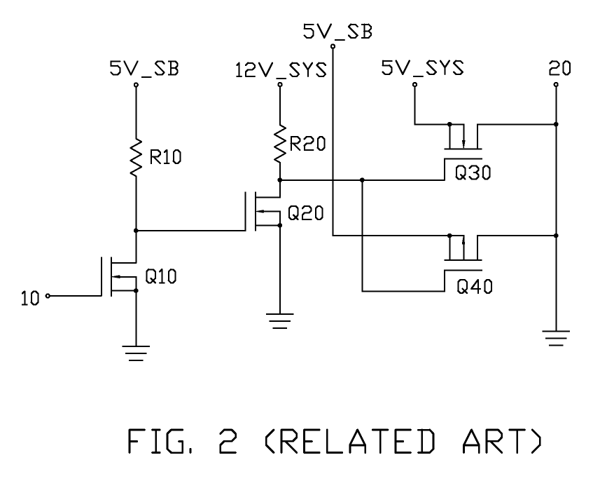

### DETAILED DESCRIPTION

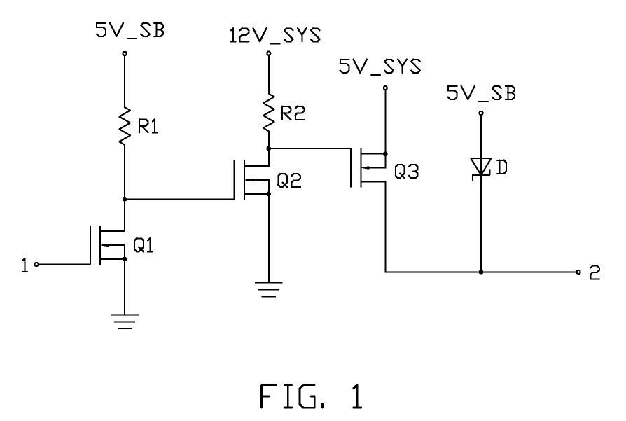

Referring to FIG. 1, a dual voltage switching circuit in accordance with an embodiment of the present invention includes a first transistor Q1, a second transistor Q2, a third transistor Q3, a Zener diode D, a first resistor R1, and a second resistor R2. In this embodiment, the three transistors are N-channel MOSFETs. The gate of the first transistor Q1 is connected to an input terminal 1. The drain of the first transistor Q1 receives a standby power voltage, for example a 5V_SB voltage, via the first resistor R1, and is connected to the gate of the second transistor Q2. The drain of the second transistor Q2 receives a first system power voltage, for example a 12V_SYS voltage, via a second resistor R2, and is connected to the gate of the third transistor Q3. The source of the third transistor Q3 receives a second system power voltage, for example a 5V_SYS voltage. The drain of the third transistor Q3 is connected to an output terminal 2. The source of the first transistor Q1 and the source of the second transistor Q2 are grounded. The anode of the Zener diode D receives the 5V_SB voltage. The cathode of the Zener diode D is connected to the drain of the third transistor Q3.

A working process of the dual voltage switching circuit includes two stages. In the first stage, the computer is in a sleep mode, and a low level voltage from the computer is input to the gate of the first transistor Q1 via the input terminal 1. The first transistor Q1 is turned off and the second transistor Q2 is turned on. An output voltage of the drain of the second transistor Q2 is at a low level. The third transistor Q3 is turned off. Therefore the output terminal 2 outputs the 5V_SB voltage in the first stage. In the second stage, the computer is in a work mode, and a power-ok (PWR-OK) signal from the computer is input to the gate of the first transistor Q1 via the input terminal 1. The first transistor Q1 is turned on and an input voltage of the gate of the second transistor Q2 is at a low level. Therefore the second transistor Q2 is turned off and the 12V_SYS voltage is output to the gates of the third transistor Q3. The third transistor Q3 is turned on. Therefore the output terminal 2 outputs the 5V_SYS in the second stage. The voltage of the anode of the Zener diode D is equal to the voltage of the cathode thereof. Therefore the 5V_SB voltage is not output to the drain of the third transistor Q3. That is, when the PWR-OK signal is input to the typical dual voltage switching circuit, the output terminal 2 outputs the 5V_SYS voltage.

When the standby power is connected to the drain of the first transistor Q1, and the second system power is connected to the source of the third transistor Q3, the dual voltage switching circuit can selectively output the standby power or the second system power. In other embodiments, the standby power, the first system power, and the second system power can be replaced by other powers.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternately embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A dual voltage switching circuit comprising:
an input terminal receiving a control signal;
a first transistor, the gate of the first transistor connected to the input terminal, the drain of the first transistor connected to a standby power, the source of the first transistor being grounded;
a second transistor, the gate of the second transistor connected to the drain of the first transistor, the drain of the second transistor connected to a first system power, the source of the second transistor being grounded;
a third transistor, the gate of the third transistor connected to the drain of the second transistor, the source of the third transistor connected to a second system power;
a Zener diode, the cathode of the Zener diode connected to the input terminal; and
an output terminal connected to the anode of the Zener diode and the drain of the third transistor, and selectively outputting the standby power or the second system power.

2. The dual voltage switching circuit as claimed in claim 1, wherein the first, second, and third transistors are N-channel metal-oxide-semiconductor field-effect transistors.

3. The dual voltage switching circuit as claimed in claim 1, wherein the standby power is a 5V standby power.

4. The dual voltage switching circuit as claimed in claim 1, wherein the first system power is a 12V system power.

5. The dual voltage switching circuit as claimed in claim 1, wherein the second system power is a 5V system power.

6. The dual voltage switching circuit as claimed in claim 1, wherein the drain of the first transistor is connected to the standby power via a resistor.

7. The dual voltage switching circuit as claimed in claim 1, wherein the drain of the second transistor is connected to the first system power via a resistor.
